(19) United States
(12) Patent Application Publication
(10) Pub. No.: US 2003/0025520 A1
(43) Pub. Date: Feb. 6, 2003

(54) Computer controlled curve tracer for extracting small and large signal parameters of semiconductor devices

(76) Inventors: Steven A. Schein, Gainesville, FL (US); Robert M. Fox, Gainesville, FL (US)

Correspondence Address: NEEDLE & ROSENBERG, P.C., Suite 1200, The Candler Building, 127 Peachtree Street, N.E., Atlanta, GA, 30303-1811, US

(21) Appl. No.: 10/119,623

(22) Filed: Apr. 9, 2002

Related U.S. Application Data
(60) Provisional application No. 60/283,979, filed on Apr. 16, 2001.

(51) Int. Cl. G01R 31/26

(52) U.S. Cl. 324/765

(57) ABSTRACT

A system and method for the analysis of electrical characterizations of semiconductor and electronic devices that utilizes a computing device to initiate a testing procedure of an electronic device by the delivery of a test voltage or current signal to the electronic device by way of the hardware interface. The electronic device's response to the voltage or current signals is measured by the hardware interface and the responsive signal is analyzed and the results displayed on a computing device.

### CROSS-REFERENCE TO RELATED PATENT APPLICATION

The benefit, pursuant to 35 U.S.C. §120, of provisional U.S. patent application Ser. No. 60/283,979, filed Apr. 16, 2001, entitled “COMPUTER CONTROLLED CURVE TRACER FOR EXTRACTING SMALL AND LARGE SIGNAL PARAMETERS OF SEMICONDUCTOR, is hereby claimed and the specification thereof incorporated herein in its entirety by this reference.”

### SUMMARY OF THE INVENTION

The system disclosed herein is a low-cost device analyzer that is used for the characterization of a wide variety of semiconductor and electronic devices. The invention comprises a software and hardware interface system for the testing of electronic devices such as BJTs, MOSFETs, LEDs, diodes and resistors. The system is capable of saving the device test result data to a standard spreadsheet file, thereby allowing the data to used in the compilation of a database or for further analysis in another software package. The disclosed system may be operated on a Macintosh™, Windows™ and Unix™ based desktop and laptop computers.

An embodiment of the current invention comprises a method for the analysis of electrical characterizations of semiconductor and electronic devices. The method comprises the steps of utilizing a computing device to initiate a testing procedure of an electronic device. Further, the method transmits a digital control signal from the computing device to a digital-to-analog converter, wherein the digital control signal is converted to an analog signal and then transmitted to a system hardware interface that comprises at least one voltage or current source to initiate a voltage or current source delivery operation within the hardware interface and delivers a test voltage or current signal to the electronic device by way of the hardware interface. Further yet, the method measures the electronic device's response to the voltage or current signals delivered by the hardware interface and converts the signals measured by the hardware interface to a digital signal, wherein the digital signal is transmitted to the computing device by way of an analog-to-digital converter and subsequently analyzes the collected signal data and displays the results to a computing device operator.

### BRIEF DESCRIPTION OF THE DRAWINGS

FIG. 1 is a block diagram representation of an embodiment of the hardware configuration of the invention.

FIGS. 2 and 2A are flow diagram representations of an embodiment of the software system of the invention.

FIGS. 3 is an exemplary graphic user interface (GUI) screen that displays the measured characteristics of a NPN I_{C} (collector current) vs. V_{be} (base emitter voltage).

FIG. 4 is an exemplary GUI screen that displays the measured characteristics of a NPN transistor.

FIG. 5 is an exemplary GUI screen that displays the measured characteristics of a PNP transistor.

FIG. 6 is an exemplary GUI screen that displays the measured characteristics of a Red LED.

FIG. 7 is an exemplary GUI screen that displays the measured characteristics of a resistor.

FIG. 8 is an exemplary GUI screen that displays the measured characteristics of a Tunnel diode.

### DETAILED DESCRIPTION OF THE INVENTION

The disclosed embodiment is intended to be illustrative only since numerous modifications and variations therein will be apparent to those of ordinary skill in the art. As utilized in the description herein and throughout the claims that follow, the meaning of “a,” “an,” and “the” include plural references also, unless the context of use clearly dictates otherwise. Additionally, the meaning of “in” includes “in” and “on” unless the context clearly dictates otherwise as the term is utilized in the description herein and throughout the claims that follow.

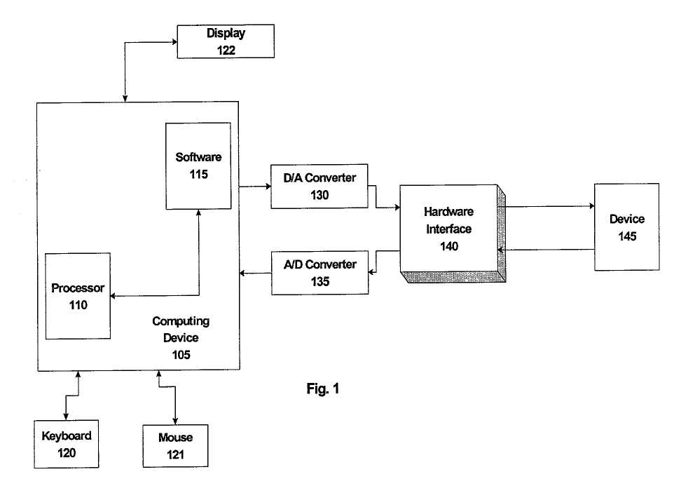

FIG. 1 is a block diagram representation of the invention. In reference to FIG. 1, the invention utilizes a computing device 105. The computing device 105 may comprise, among other components, software 115, a processor 110, a display device 122 and user input devices such as a keyboard 120 and mouse 121. A user may initiate the testing procedures of an electronic device 145 directly through interaction with the computing device's 105 user input devices. A digital control signal is transmitted from the computing device 105 to a digital to analog converter 130 (D/A), where the converted signal is then transmitted to the systems hardware interface 140. The hardware interface 140 of the system may comprise one or more voltage/current sources and electronic measuring equipment that is known in the art for testing semiconductor devices. The hardware interface 140 is electrically coupled to the appropriate terminals of the device 145 that is to be analyzed. The hardware interface 140 delivers test voltage and/or current signals to the device 145 and measures the device's 145 response voltage and/or current signals for conversion to digital signals, which are transmitted back to the computing device 105 by way of an analog to digital converter 135 (A/D). The software 115 executed by the processor 110 then analyzes the collected data and results are displayed to the user.

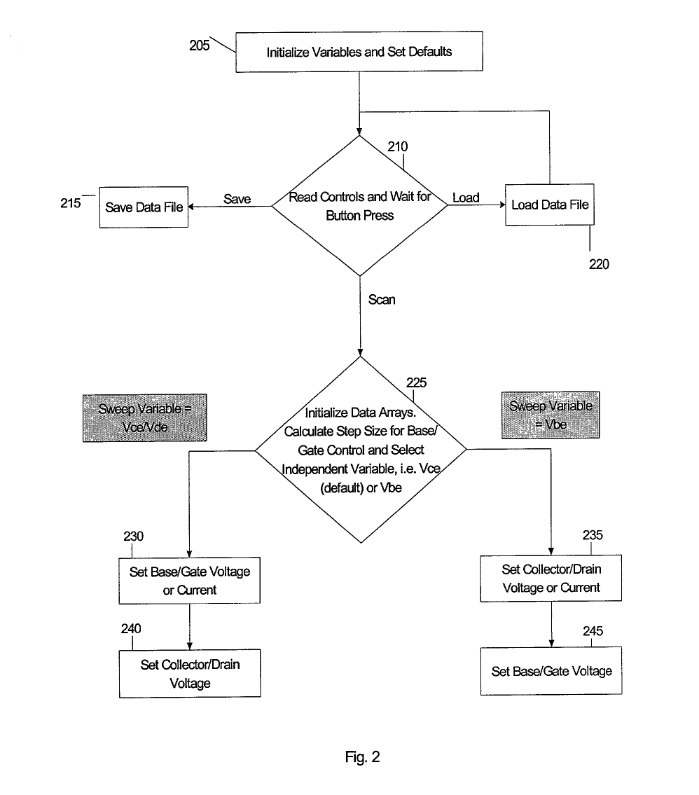

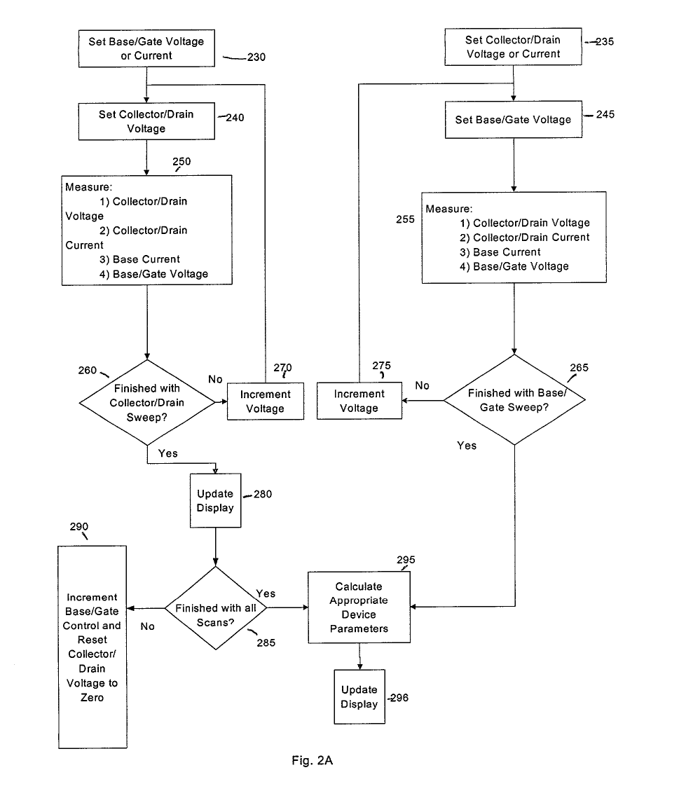

FIGS. 2 and 2A are flow diagram representations of an embodiment of the software system of the present invention. The flowchart presents the steps performed in the generation of test voltages and/or currents that are applied to the device in order to measure the appropriate voltage or current responses from the device. Initially, the sweep variables and system defaults are set at step 205. At step 210, a decision function is accessed. Step 215 represents a decision to save the current data file. Step 220 represents a decision to load a data file, wherein upon the loading of the data file the process returns to the decision function of step 210. The scanning operation is accessed at step 225. This step initializes the data arrays, calculates the step size for the base/gate control and the independent variables V_{ce} or V_{be} selected at step 205.

Upon the selection of a V_{be} sweep variable the process moves on to step 235 where the voltage or current of the collector/drain is set. Next, at step 245, the base/gate voltage is set. The process measures the collector/drain voltage, the collector/drain current, the base current and the base/gate voltage at step 255. The step of 265 determines if the base/gate sweep is finished. If the base/gate sweep is not finished, then at 275 the voltage is incremented and the process returns to step 245. If the base/gate sweep is finished, then the process proceeds to step 295 the appropriate parameters of the device are calculated and subsequently displayed at step 296.

At step 225, the process proceeds to step 230 upon the selection of a V_{ce} sweep variable. Next, at step 230, the base/gate voltage or current is set. Further, at step 240, the collector/drain voltage is set. Next, at step 250, the measurements of the collector/drain voltage and current, the base current and the base/gate voltage are obtained by the system. At step 260, a decision is made as to whether the collector/drain sweep is finished. If the sweep is not finished the process proceeds t step 270, where the voltage is incremented and the process returns to step 240. If the sweep is finished, then the process proceeds to step 280 where the display is updated. At step 285, a decision is made as to whether all scans are complete. If the scans are not complete then the process proceeds to step 290 where the base/gate control is incremented and the collector/drain voltage is set to zero. If the scans are complete, then at step 295 the appropriate device parameters are calculated and displayed at step 296.

One of ordinary skill in the art would appreciate and understand that the testing and measured voltage or currents utilized and received by the system would vary and ultimately depend on the type of device that is being tested.

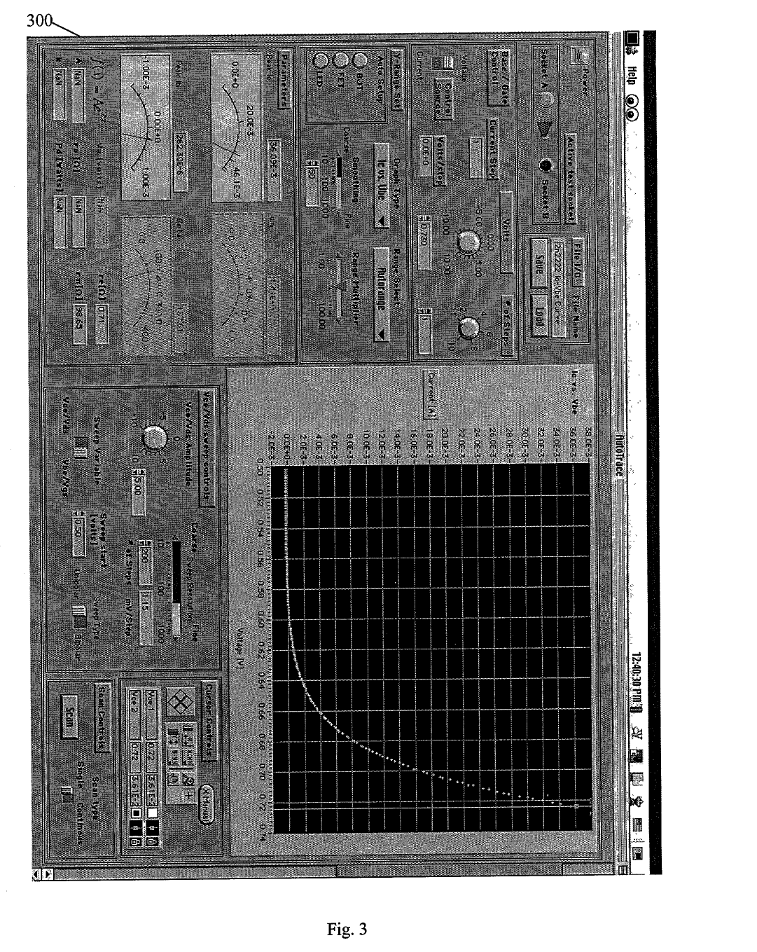

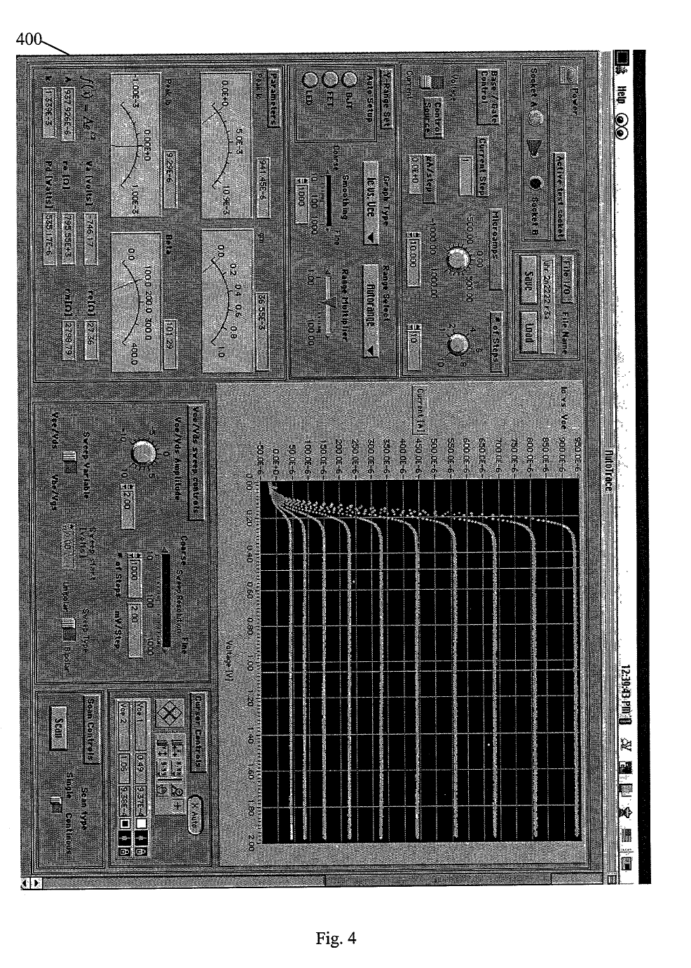

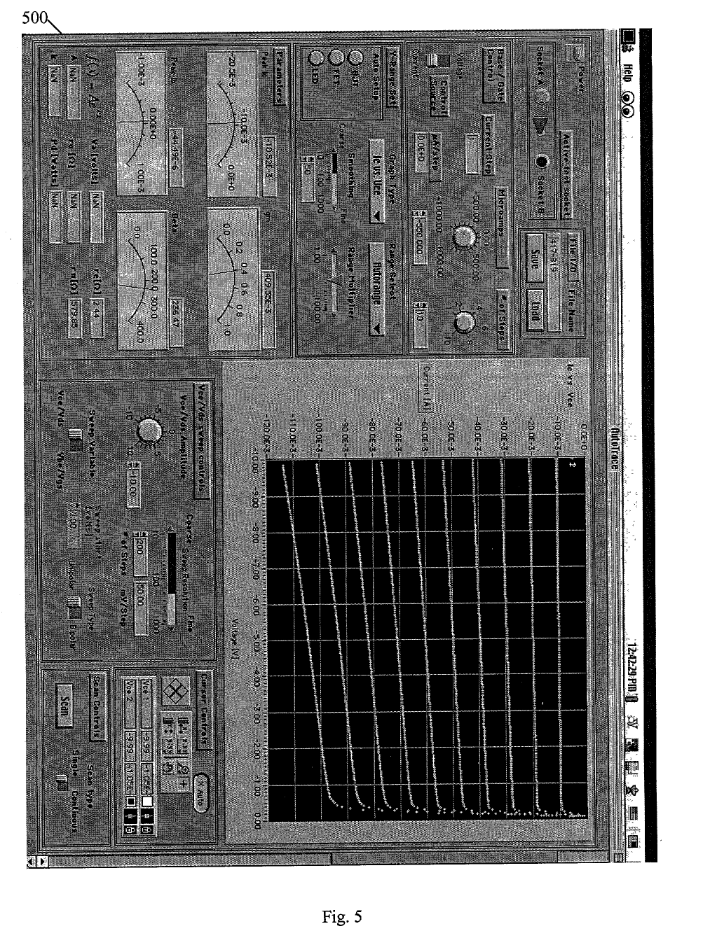

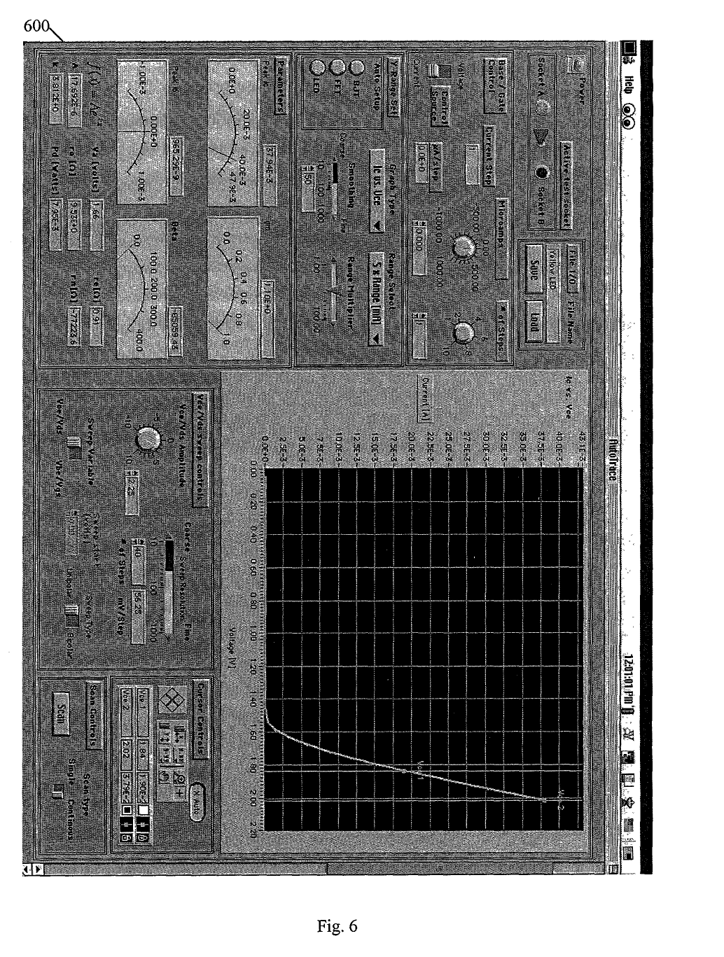

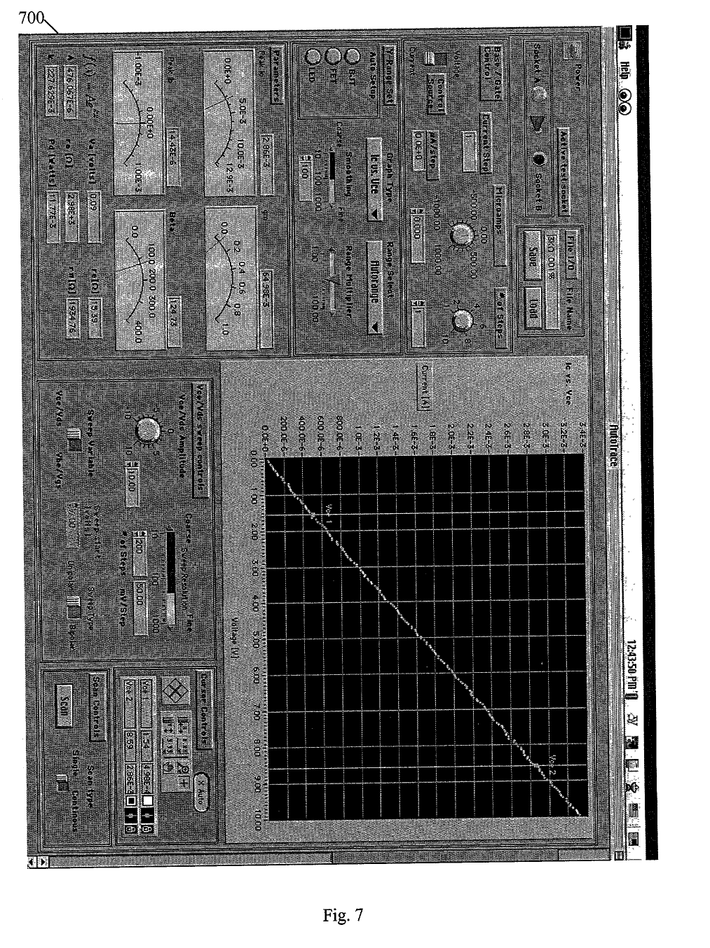

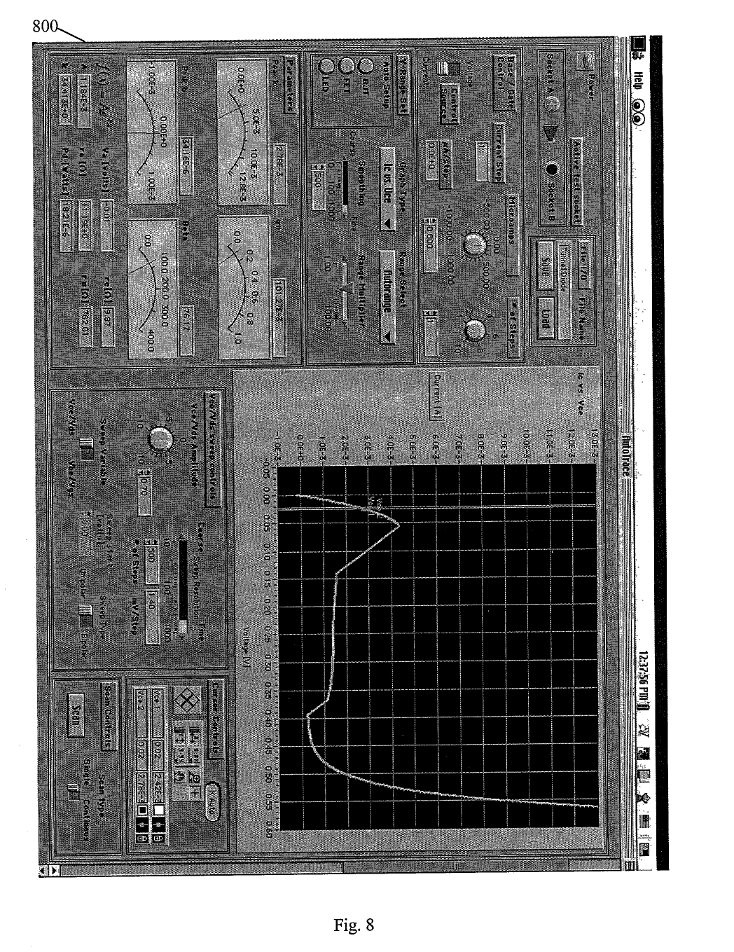

FIGS. 3-8 are screen-shot representations of the invention's GUI (300, 400, 500, 600, 700 and 800). The GUI functions as a virtual oscilloscope display that the user can manipulate by way of the software that is utilized and the standard PC user input devices. For example, a user may change parameters of the sweep variables. If necessary, the software will generate appropriate digital control signals that are converted to analog signals and delivered to the device by the hardware interface. The measured signals are received and used to adjust the displayed data, graphs, etc. or the GUI screen that the user interfaces with. The exemplary screen-shots show how the variables are initialized depending on the device to be tested, the type of curve to be traced for the device, etc. All of these parameters are processed by the software to create the desired testing, measurement and display conditions.

Other aspects of the invention may be found from the attached drawings and other related materials such as a detailed review of the various functions offered by the present invention, which are integral parts of this disclosure. Moreover, other embodiments of the invention will be apparent to those skilled in the art from consideration of the specification and practice of the invention disclosed herein. It is intended that the specification and examples be considered as exemplary only

What is claimed:

1. A method for the analysis of electrical characterizations of semiconductor and electronic devices comprising the steps of:
utilizing a computing device to initiate a testing procedure of an electronic device;
transmitting a digital control signal from the computing device to a digital-to-analog converter, wherein the digital control signal is converted to an analog signal and then transmitted to a system hardware interface that comprises at least one voltage or current source to initiate a voltage or current source delivery operation within the hardware interface;
delivering a test voltage or current signal to the electronic device by way of the hardware interface;
measuring the electronic device's response to the voltage or current signals delivered by the hardware interface;
converting the voltage or current signal measured by the hardware interface to a digital signal, wherein the digital signal is transmitted to the computing device by way of an analog-to-digital converter; and
analyzing the collected signal data and displaying the results to a computing device operator.
